(19) United States
(12) Patent Application Publication
(10) Pub. No.: US 2006/0063290 A1
(43) Pub. Date: Mar. 23, 2006

(54) Method of fabricating metal-insulator-metal capacitor

(75) Inventor: Seok-Jun Won, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/197,881

(22) Filed: Aug. 5, 2005

(30) Foreign Application Priority Data
Sep. 23, 2004 (KR) 10-2004-0076671

(51) Int. Cl. H01L 21/00

(52) U.S. Cl. 438/28

(57) ABSTRACT

Provided is a method of fabricating a metal-insulator-metal (MIM) capacitor. This method includes forming a metal node on a substrate. A metal nitride node is formed on the substrate having the metal node by using a nitridation process. A dielectric is formed to surround a top surface and sidewalls of the metal nitride node. An upper electrode is formed on the dielectric. The metal node may be composed of a titanium (Ti) layer, a titanium nitride (TiN) layer and a tungsten (W) layer, which are sequentially stacked. In the nitridation process, a gas nitridation method or a plasma nitridation method may be used.

### CROSS-REFERENCE TO RELATED APPLICATION

This application claims priority from Korean Patent Application No. 2004-76671, filed Sep. 23, 2004, the contents of which are hereby incorporated herein by reference in their entirety as if set forth fully herein.

### BACKGROUND OF INVENTION

1. Technical Field

The present invention relates to a method of fabricating a semiconductor device, and more particularly, to a method of fabricating a capacitor having metal electrodes.

2. Discussion of the Related Art

Semiconductor devices include transistors, capacitors and interconnections. Each of the capacitors is composed of an upper electrode, a lower electrode overlapping with the upper electrode, and a dielectric interposed therebetween. To implement the capacitor, a method with a metal-insulator-silicon (MIS) structure is used. In the capacitor of the MIS structure, a polysilicon electrode is used as a storage electrode which is the lower electrode. A metal electrode is used as a plate electrode which is the upper electrode. The dielectric is interposed between the storage electrode and the plate electrode. In this MIS structure, however, an oxidation reaction occurs at an interface between the polysilicon electrode and the dielectric and changes electrical properties of the capacitor. Further, the capacitor exhibits non-uniform capacitance depending on the size of a voltage applied to the metal plate electrode. For example, if the polysilicon storage electrode is doped with an N-type impurity and a negative voltage is applied to the metal plate electrode, holes are induced onto the surface of the polysilicon storage electrode. That is, a depletion layer may be formed on the surface of the lower electrode, and the width of the depletion layer is changed according to the applied negative voltage. Because of this, the capacitance of the capacitor is changed according to the size of the voltage applied to the electrodes. Thus, the capacitor of the MIS structure is not suitable for semiconductor devices requiring advance characteristics.

In order to solve the aforementioned problems, a capacitor with metal electrodes, namely, a metal-insulator-metal (MIM) capacitor has been proposed.

FIGS. 1 to 3 are sectional views illustrating a conventional capacitor fabricating method.

Referring to FIG. 1, a lower interlayer dielectric 15 is formed on a semiconductor substrate (not shown). A conductive plug 16 is formed within the lower interlayer dielectric 15 using a typical damascene process. The conductive plug 16 is typically composed of a titanium (Ti) layer 17, a titanium nitride (TiN) layer 18, and a tungsten (W) layer 19, which are sequentially stacked. An upper interlayer dielectric 20 is formed on the overall surface of the semiconductor substrate having the conductive plug 16. To expose the conductive plug 16, a trench 21 is formed by patterning the upper interlayer dielectric 20 and the lower interlayer dielectric 15. The trench 21 is formed to have a width greater than that of the conductive plug 16. Further, the trench 21 is formed to have a bottom surface positioned under a top surface of the conductive plug 16. That is, a portion of the conductive plug 16 protrudes into the trench 21. A lower electrode layer 23 and a dielectric 25 are sequentially formed on the overall surface of the semiconductor substrate having the trench 21. The lower electrode layer 23 and the dielectric 25 are formed to cover the protruded portion of the conductive plug 16 and extend to cover the inner walls of the trench 21. A titanium nitride (TiN) layer is widely used as a material for forming the lower electrode layer 23.

Referring to FIG. 2, a barrier metal layer 27 and an upper electrode layer 28 are sequentially formed on the overall surface of the semiconductor substrate having the dielectric 25. A titanium nitride (TiN) layer is widely used as a material for forming the barrier metal layer 27. A tungsten (W) layer is widely used as a material for forming the upper electrode layer 28.

Referring to FIG. 3, a lower electrode 23′, a dielectric pattern 25′, a barrier metal pattern 27′ and an upper electrode pattern 28′ are formed by planarizing the lower electrode layer 23, the dielectric 25, the barrier metal layer 27 and the upper electrode layer 28. The barrier metal pattern 27′ and the upper electrode pattern 28′ act as an upper electrode 30. In the planarization, a chemical mechanical polishing (CMP) process is widely used which employs the upper interlayer dielectric 20 as a stop layer. However, a portion B, where the lower electrode 23′, the dielectric pattern 25′ and the upper electrode 30 are adjacent and exposed, is vulnerable to contamination. That is, a leakage current is prone to occur in the portion B where the lower electrode 23′, the dielectric pattern 25′ and the upper electrode 30 are adjacent and exposed.

In order to address this problem, the lower electrode layer 23 may be omitted. When the lower electrode layer 23 is omitted, the dielectric 25 is formed to surround the protruded portion of the conductive plug 16. However, the sidewall of the conductive plug 16 is formed of the titanium (Ti) layer 17, and the top surface of the conductive plug 16 is formed of the tungsten (W) layer 19. Further, an oxide layer is widely used as a material for forming the dielectric 25. When the dielectric 25 is deposited on the titanium (Ti) layer 17 and the tungsten (W) layer 19, oxygen is consumed to oxidize the titanium (Ti) layer 17 and the tungsten (W) layer 19 and becomes insufficient for the dielectric 25, which is initially deposited. The dielectric 25 deposited with the oxygen being insufficient will have a degraded leakage current property and reliability. Further, as the titanium (Ti) layer 17 and the tungsten (W) layer 19 are not oxidized uniformly, the titanium (Ti) layer 17 and the tungsten (W) layer 19 will have poor surface roughness. In addition, an interfacial oxide layer is formed with a poor layer quality on the surfaces of the titanium (Ti) layer 17 and the tungsten (W) layer 19. This results in a reduced capacitance.

To solve the aforementioned problems, there has been proposed a capacitor having new metal electrodes. The capacitor is disclosed in U.S. Pat. No. 6,720,604 B1, entitled “Capacitor for an integrated circuit” by Fritzinger et al.

FIG. 4 is a sectional view illustrating the capacitor disclosed in U.S. Pat. No. 6,720,604 B1.

Referring to FIG. 4, a conductive plug is disposed in an interlayer dielectric 1 having a trench. The conductive plug is composed of a titanium (Ti) layer 3, a titanium nitride (TiN) layer 5 and a tungsten (W) layer 7, which are sequentially stacked. An upper region of the conductive plug is protruded into the trench. A lower electrode 9 is disposed to surround the protruded portion of the conductive plug. The lower electrode 9 is formed of a tungsten (W) layer or a tungsten nitride (WN) layer. An upper electrode 13 is disposed to surround the lower electrode 9, and a dielectric 11 is interposed between the lower electrode 9 and the upper electrode 13. However, in order to implement the capacitor which is disclosed in the U.S. Pat. No. 6,720,604 B1, it is necessary to have deposition and patterning processes for forming the lower electrode 9. Further, if the lower electrode 9 is formed of the tungsten (W) layer, the leakage current property and reliability of the dielectric 11 are degraded, as previously stated.

Consequently, there exists a need for a technique of fabricating a metal-insulator-metal (MIM) capacitor capable of preventing the leakage current property and the reliability from being degraded.

### SUMMARY OF THE INVENTION

Therefore, the present invention is directed to a method of fabricating a capacitor with metal electrodes, capable of preventing a leakage current property and a reliability from being degraded.

In accordance with an exemplary embodiment, the present invention provides a method of fabricating a metal-insulator-metal (MIM) capacitor. This method includes forming a metal node on a substrate. A metal nitride node is formed on the substrate having the metal node by a nitridation process. A dielectric is formed to surround a top surface and sidewalls of the metal nitride node. An upper electrode is formed on the dielectric.

The substrate may be a semiconductor substrate, such as a silicon substrate.

The metal node may be formed of a titanium (Ti) layer, a titanium nitride (TiN) layer and a tungsten (W) layer, which are sequentially stacked. Alternatively, the metal node may be formed of a tungsten (W) layer.

In the nitridation process, a gas nitridation method or a plasma nitridation method may be used. The gas nitridation method may use, for example, ammonia (NH₃) gas as a nitridation agent and may include processing for 10 to 900 seconds at a temperature of 500° C. to 900° C. The plasma nitridation may use, for example, ammonia (NH₃) or nitrogen (N₂) plasma as a nitridation agent and may include processing for 10 to 900 seconds at a temperature of 300° C. to 600° C. As a result, metal nitride layers may be formed on the exposed portion of the metal node. Here, when the metal node is composed of a titanium (Ti) layer, a titanium nitride (TiN) layer and a tungsten (W) layer, which are sequentially stacked, the tungsten nitride (WN) layer may be formed on the top surface of the metal node, and concurrently, the titanium nitride (TiN) layers may be formed on the exposed sidewalls of the metal node. On the other hand, when the metal node is formed of only the tungsten (W) layer, a tungsten nitride (WN) layer may be formed on the top surface and the exposed sidewalls of the metal node.

The dielectric may be formed of at least one material layer selected from the group consisting of a silicon nitride (SiN) layer, an aluminum oxide (AlO) layer, a hafnium oxide (HfO) layer, a tantalum oxide (TaO) layer, a lanthanum oxide (LaO) layer, a zirconium oxide (ZrO) layer, a titanium oxide (TiO) layer, and a niobium oxide (NbO) layer. Alternatively, the dielectric may be formed of a multi-layered layer of at least two selected from the group consisting of a silicon nitride (SiN) layer, an aluminum oxide (AlO) layer, a hafnium oxide (HfO) layer, a tantalum oxide (TaO) layer, a lanthanum oxide (LaO) layer, a zirconium oxide (ZrO) layer, a titanium oxide (TiO) layer, and a niobium oxide (NbO) layer.

The upper electrode may be formed of a barrier metal pattern and an upper metal electrode pattern, which are sequentially stacked. Alternatively, the upper electrode may be formed of only the upper metal electrode pattern. The upper metal electrode pattern may be formed of a tungsten (W) layer. The barrier metal pattern may be formed of a titanium nitride (TiN) layer.

In accordance with, another aspect, the present invention provides a method of fabricating a metal-insulator-metal (MIM) capacitor, including forming a lower interlayer dielectric on a substrate and forming a metal node in the lower interlayer dielectric. An upper interlayer dielectric is formed on the overall surface of the substrate having the metal node. The upper interlayer dielectric and the lower interlayer dielectric are patterned, thereby exposing an upper surface and sidewalls of the metal node. A metal nitride node is formed on the exposed portion of the metal node using a nitridation process. A dielectric is formed to surround a top surface and exposed sidewalls of the metal nitride node. An upper electrode is formed on the dielectric.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1 to 4 are sectional views illustrating a conventional capacitor fabricating method.

FIGS. 5 to 10 are sectional views illustrating a method of fabricating an MIM capacitor according to an embodiment of the present invention.

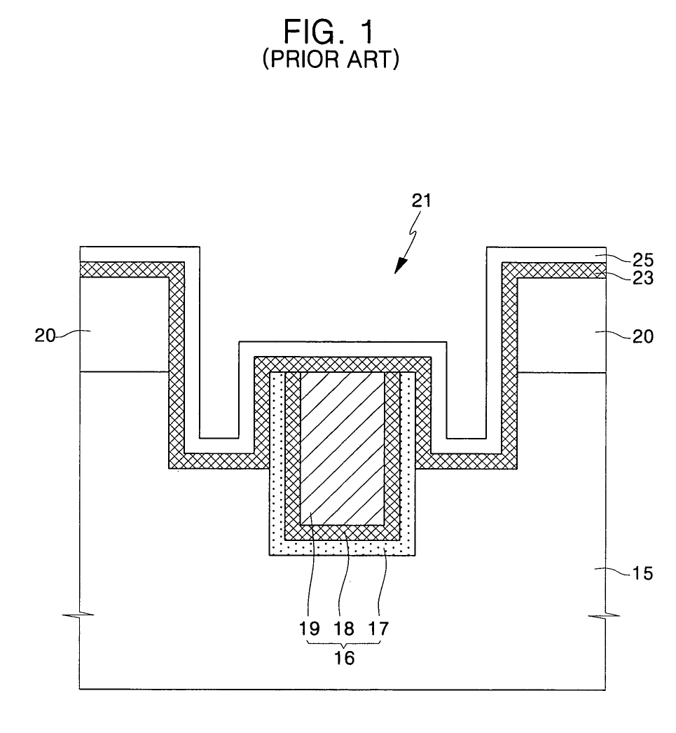

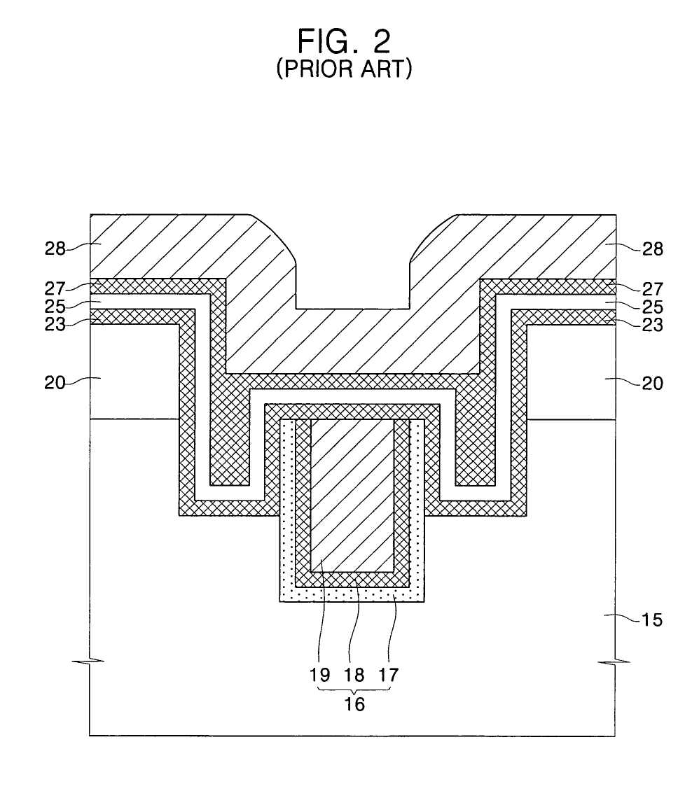

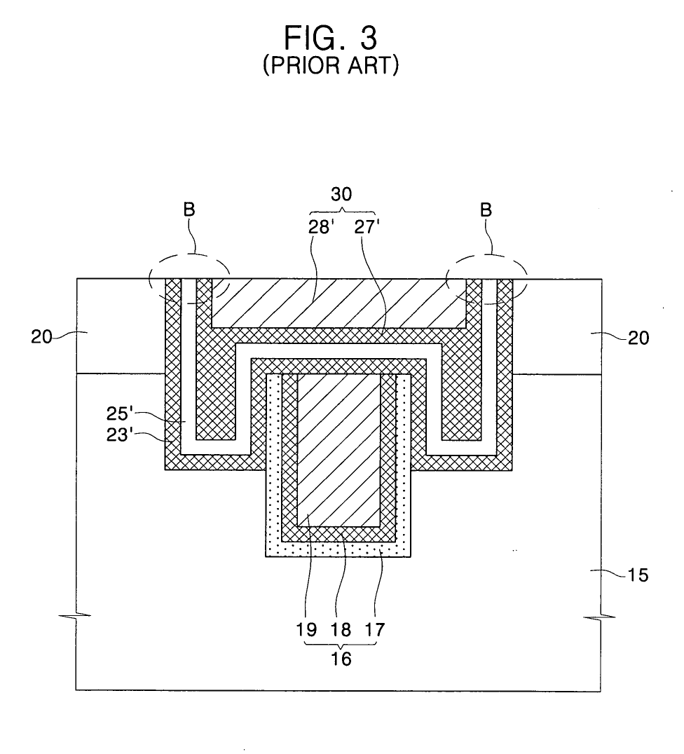

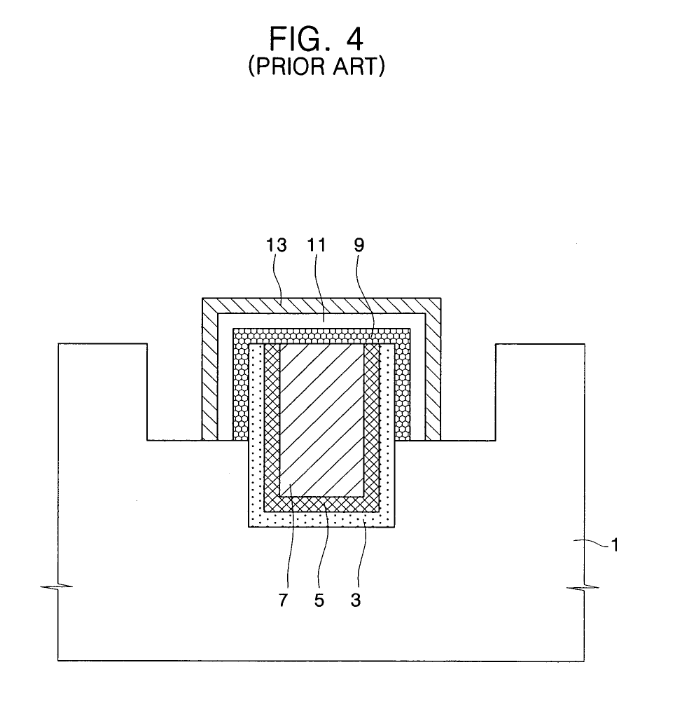

### DETAILED DESCRIPTION OF THE INVENTION

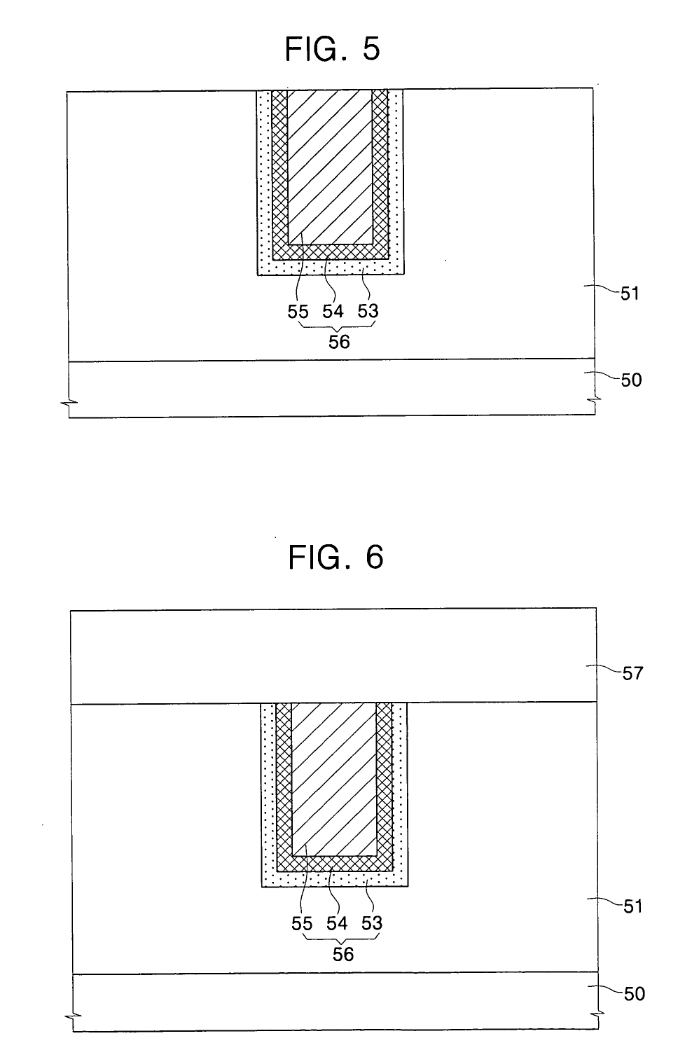

FIGS. 5 to 10 are sectional views illustrating a method of fabricating an MIM capacitor according to an embodiment of the present invention.

Referring to FIG. 5, a lower interlayer dielectric 51 is formed on a substrate 50. A metal node 56 is formed within the lower interlayer dielectric 51 by a typical damascene process. The substrate 50 may be a semiconductor substrate, such as a silicon substrate. The lower interlayer dielectric 51 may be formed of, for example, an insulating layer such as a plasma-tetra ethyl ortho silicate (P-TEOS) layer. The metal node 56 may be composed of a titanium (Ti) layer 53, a titanium nitride (TiN) layer 54 and a tungsten (W) layer 55, which are sequentially stacked. Alternatively, the metal node 56 may be formed of only a metal layer, such as the tungsten (W) layer 55. Top surfaces of the lower interlayer dielectric 51 and the metal node 56 may be formed substantially coplanar.

Referring to FIG. 6, an upper interlayer dielectric 57 is formed on an overall surface of the substrate 50 having the metal node 56. The upper interlayer dielectric 57 may be formed of an insulating layer, such as a plasma-tetra ethyl ortho silicate (P-TEOS) layer.

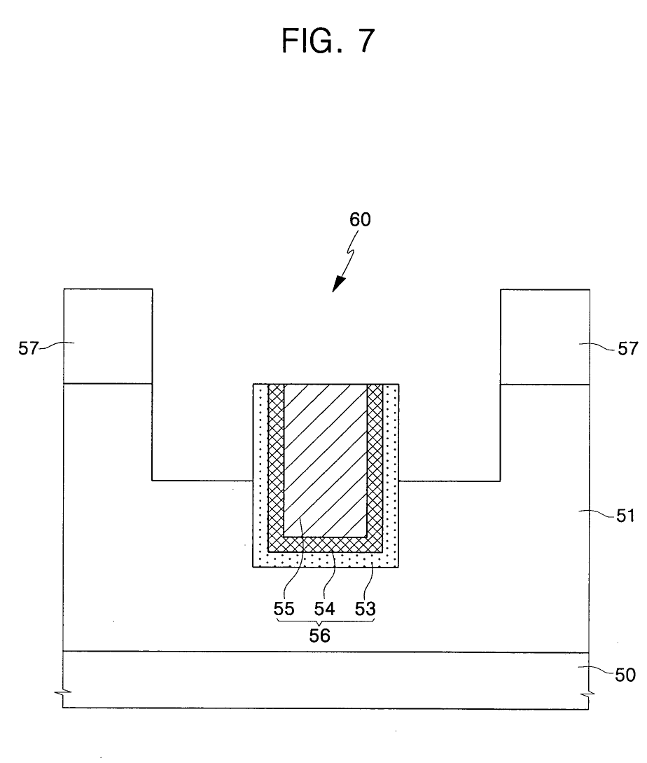

Referring to FIG. 7, a trench 60 is formed to expose a top surface and sidewalls of the metal node 56 by successively patterning the upper interlayer dielectric 57 and the lower interlayer dielectric 51.

A process of patterning the upper interlayer dielectric 57 and the lower interlayer dielectric 51 includes forming a photoresist pattern (not shown) to cover the substrate 50 having the upper interlayer dielectric 57 formed thereon, etching the upper interlayer dielectric 57 and the lower interlayer dielectric 51 using the photoresist pattern as an etch mask, and removing the photoresist pattern.

The trench 60 may be formed to have a width greater than that of the metal node 56, and to have a bottom surface positioned under a top surface of the metal node 56. That is, a portion of the metal node 56 is protruded into the trench 60. Here, when the metal node 56 is composed of the titanium (Ti) layer 53, the titanium nitride (TiN) layer 54 and the tungsten (W) layer 55 which are sequentially stacked, the top surface of the tungsten (W) layer 55 and the sidewalls of the titanium (Ti) layer 53 may be exposed into the trench 60. Further, when the metal node 56 is formed of only the tungsten (W) layer 55, the top surface and the sidewalls the tungsten (W) layer 55 may be exposed into the trench 60.

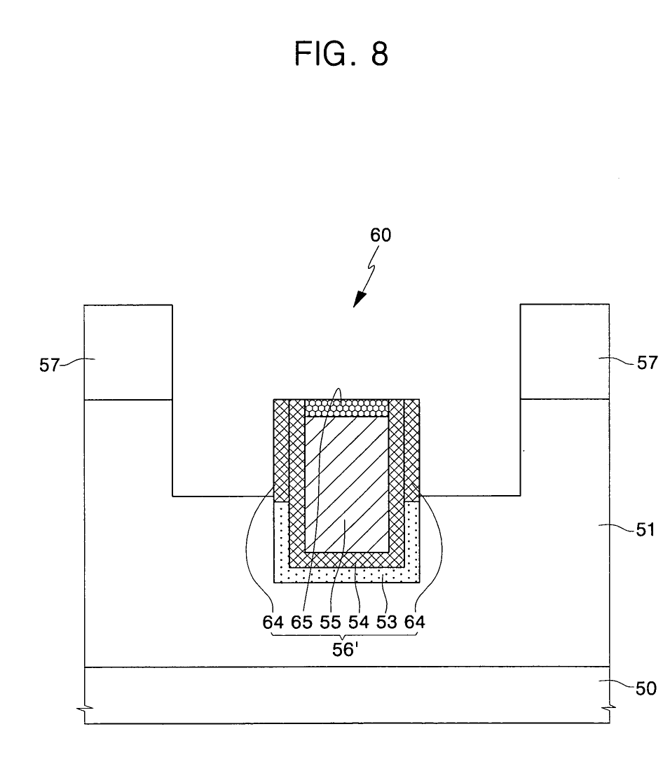

Referring to FIG. 8, a metal nitride node 56′ is formed on the substrate 50 having the trench 60 by using a nitridation process. Metal nitride layers 64 and 65 may be formed on the exposed portion of the metal node 56 by the nitridation process. Here, when the metal node 56 is composed of the titanium (Ti) layer 53, the titanium nitride (TiN) layer 54 and the tungsten (W) layer 55, which are sequentially stacked, the tungsten nitride (WN) 65 layer may be formed on the top surface of the metal node 56, and concurrently, the titanium nitride (TiN) layers 64 may be formed on the exposed sidewalls of the metal node 56. On the other hand, when the metal node 56 is formed of only the tungsten (W) layer 55, the tungsten nitride (WN) layer 65 may be formed on the top surface and the exposed sidewalls of the metal node 56.

In the nitridation process, a gas nitridation method or a plasma nitridation method may be used. The gas nitridation method may use, for example, ammonia (NH₃) gas as a nitridation agent and may include processing for 10 to 900 seconds at a temperature of 500° C. to 900° C. The plasma nitridation method may use, for example, ammonia (NH₃) or nitrogen (N₂) plasma as the nitridation agent and may include processing for 10 to 900 seconds at a temperature of 300° C. to 600° C.

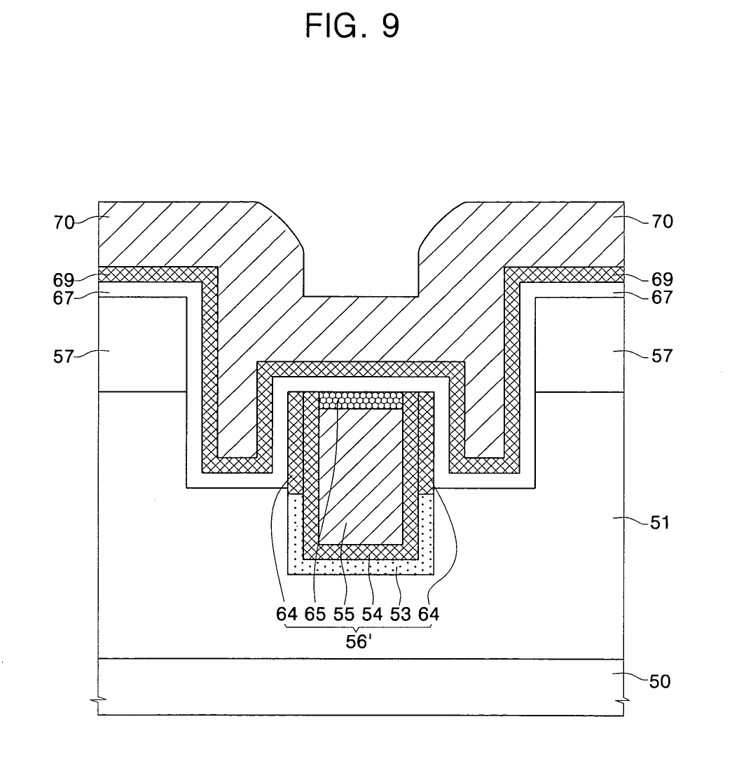

Referring to FIG. 9, a dielectric 67, a barrier metal layer 69 and an upper metal electrode layer 70 are sequentially formed on the substrate 50 having the metal nitride node 56′. The dielectric 67 may be formed of at least one material layer selected from the group consisting of a silicon nitride (SiN) layer, an aluminum oxide (AlO) layer, a hafnium oxide (HfO) layer, a tantalum oxide (TaO) layer, a lanthanum oxide (LaO) layer, a zirconium oxide (ZrO) layer, a titanium oxide (TiO) layer, and a niobium oxide (NbO) layer. Alternatively, the dielectric 67 may be formed of a multi-layered layer of at least two selected from the group consisting of a silicon nitride (SiN) layer, an aluminum oxide (AlO) layer, a hafnium oxide (HfO) layer, a tantalum oxide (TaO) layer, a lanthanum oxide (LaO) layer, a zirconium oxide (ZrO) layer, a titanium oxide (TiO) layer, and a niobium oxide (NbO) layer. The barrier metal layer 69 may be formed of a titanium nitride (TiN) layer. The upper metal electrode layer 70 may be formed of a tungsten (W) layer.

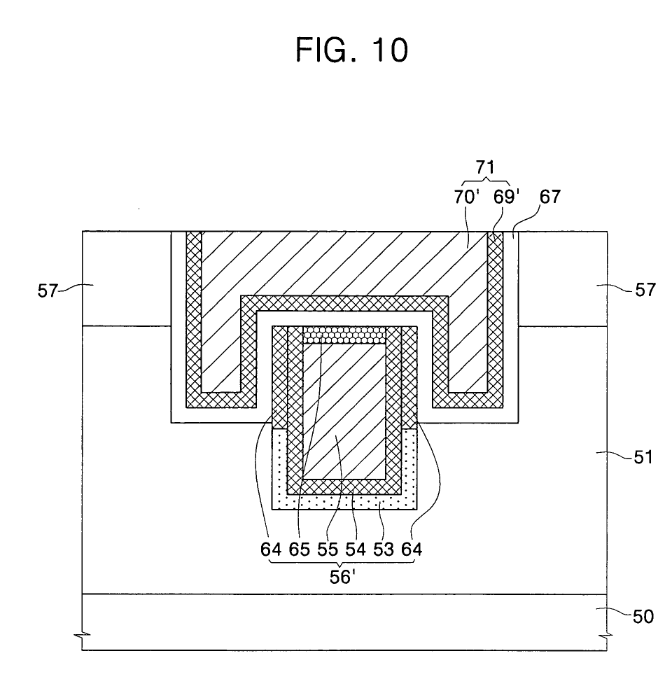

Referring to FIG. 10, a barrier metal pattern 69′ and an upper metal electrode pattern 70′ are formed by planarizing the barrier metal layer 69 and the upper metal electrode layer 70. The planarization may use a chemical mechanical polishing (CMP) process which employs the upper interlayer dielectric 57 as a stop layer. The barrier metal pattern 69′ and the upper metal electrode pattern 70′ act as an upper electrode 71. However, the barrier metal pattern 69′ may be omitted. The top surfaces of the upper electrode 71 and the upper interlayer dielectric 57 may be formed substantially coplanar.

The metal nitride node 56′ is used as a lower electrode. Further, the metal nitride node 56′ has the metal nitride layers 64 and 65 formed by the nitridation process. Even though an oxide layer is formed on the metal nitride node 56′ upon depositing the dielectric 67, the metal nitride node 56′ is no longer oxidized due to the presence of the metal nitride layers 64 and 65. Therefore, it is possible to form the dielectric 67 having an excellent leakage current property and reliability. In addition, even though the oxide layer is formed on the metal nitride node 56′ upon depositing the dielectric 67, an interfacial oxide layer having a poor layer quality is prevented from being formed on the metal nitride node 56′. That is, it enhances a reduced capacitance caused by the interfacial oxide layer.

The metal-insulator-metal (MIM) capacitor fabricated according to the present invention may be useful for semiconductor devices requiring a relatively lower capacitance per unit area as compared to a dynamic random access memory (DRAM), like a pseudo static random access memory (SRAM).

As described above, according to the present invention, a metal nitride node is formed which is used as a lower electrode. The metal nitride node has metal nitride layers which are formed by a nitridation process. A dielectric and an upper electrode, which are sequentially stacked, are formed on the metal nitride node. Accordingly, even though the oxide layer is deposited as the dielectric, the metal nitride node is no longer oxidized. As a result, it is possible to fabricate a metal-insulator-metal (MIM) capacitor having excellent leakage current property and reliability.

What is claimed is:

1. A method of fabricating a metal-insulator-metal (MIM) capacitor, comprising:
forming a metal node on a substrate;
forming a metal nitride node on the substrate having the metal node using a nitridation process;
forming a dielectric surrounding a top surface and sidewalls of the metal nitride node; and
forming an upper electrode on the dielectric.

2. The method according to claim 1, wherein the substrate is a semiconductor substrate.

3. The method according to claim 1, wherein the metal node comprises a titanium (Ti) layer, a titanium nitride (TiN) layer and a tungsten (W) layer, which are sequentially stacked.

4. The method according to claim 1, wherein the metal node comprises a tungsten (W) layer.

5. The method according to claim 1, wherein the metal nitride node comprises a metal nitride layer.

6. The method according to claim 5, wherein the metal nitride layer comprises a titanium nitride (TiN) layer and a tungsten nitride (WN) layer.

7. The method according to claim 5, wherein the metal nitride layer is a tungsten nitride (WN) layer.

8. The method according to claim 5, wherein the metal nitride layer is formed by performing a thermal reaction in an ammonia (NH₃) atmosphere.

9. The method according to claim 5, wherein the metal nitride layer is formed by a plasma method using one of ammonia (NH₃) and nitrogen (N₂).

10. The method according to claim 1, wherein the dielectric is formed of at least one material layer selected from the group consisting of a silicon nitride (SiN) layer, an aluminum oxide (AlO) layer, a hafnium oxide (HfO) layer, a tantalum oxide (TaO) layer, a lanthanum oxide (LaO) layer, a zirconium oxide (ZrO) layer, a titanium oxide (TiO) layer, and a niobium oxide (NbO) layer.

11. The method according to claim 1, wherein the dielectric is formed of a multi-layered layer including at least two selected from the group consisting of a silicon nitride (SiN) layer, an aluminum oxide (AlO) layer, a hafnium oxide (HfO) layer, a tantalum oxide (TaO) layer, a lanthanum oxide (LaO) layer, a zirconium oxide (ZrO) layer, a titanium oxide (TiO) layer, and a niobium oxide (NbO) layer.

12. The method according to claim 1, wherein the upper electrode comprises a barrier metal pattern and an upper metal electrode pattern, which are sequentially stacked.

13. The method according to claim 1, wherein the upper electrode is formed of an upper metal electrode pattern.

14. The method according to claim 12, wherein the upper metal electrode pattern is formed of a tungsten (W) layer.

15. The method according to claim 12, wherein the barrier metal pattern is formed of a titanium nitride (TiN) layer.

16. A method of fabricating a metal-insulator-metal (MIM) capacitor, comprising:
forming a lower interlayer dielectric on a substrate;
forming a metal node in the lower interlayer dielectric;
forming an upper interlayer dielectric on an overall surface of the substrate having the metal node;
patterning the upper interlayer dielectric and the lower interlayer dielectric, thereby exposing an upper surface and sidewalls of the metal node;
forming a metal nitride node on the exposed portion of the metal node using a nitridation process;
forming a dielectric surrounding a top surface and exposed sidewalls of the metal nitride node; and
forming an upper electrode on the dielectric.

17. The method according to claim 16, wherein the metal nitride node comprises a metal nitride layer.

18. The method according to claim 17, wherein the metal nitride layer comprises a titanium nitride (TiN) layer and a tungsten nitride (WN) layer.

19. The method according to claim 17, wherein the metal nitride layer is formed by performing a thermal reaction in an ammonia (NH₃) atmosphere.

20. The method according to claim 17, wherein the metal nitride layer is formed by a plasma method using one of ammonia (NH₃) and nitrogen (N₂).
